(19) United States
(12) Patent Application Publication
(10) Pub. No.: US 2025/0314681 A1
(43) Pub. Date: Oct. 9, 2025

(54) METHOD FOR CALCULATING CARBON EMITTED BY AN ELECTRONIC DEVICE, ELECTRONIC DEVICE AND STORAGE MEDIUM

(71) Applicant: Dynabook Technology (Hangzhou) Inc., Hangzhou (CN)

(72) Inventors: WEN-XIANG ZHANG, Hangzhou (CN); Lu-Te Chen, Taipei (TW); Jun-Kai Liu, Hangzhou (CN)

(21) Appl. No.: 18/765,406

(22) Filed: Jul. 8, 2024

(30) Foreign Application Priority Data
Apr. 9, 2024 (CN) 202410425422.7

(51) Int. Cl. G01R 22/10

(52) U.S. Cl. CPC G01R 22/10

(57) ABSTRACT

A method for calculating carbon emitted by an electronic device is provided. The method includes obtaining a type of an adapter that is connected to the electronic device in response that the electronic device is in a charging state; detecting a current and a voltage of the adapter in response that the type of the adapter is a first type; determining a conversion efficiency corresponding to the adapter with the adapter with the first type based on a plurality of parameters of the adapter with the first type; and calculating the carbon emitted by the electronic device according to the current, the voltage, the conversion efficiency and a preset conversion coefficient. The method can improve the accuracy of calculating the carbon emitted by the electronic device.

### FIELD

The present disclosure relates to a field of energy conservation and environmental protection technology, in particular to a method for calculating carbon emitted by an electronic device, an electronic device, and a storage medium.

### BACKGROUND

Electronic device will produce environmental pollutants such as carbon dioxide during a charging process. In related technologies, a method for calculating carbon emitted by an electronic device by detecting a battery capacity and a battery voltage of the electronic device are detected to calculate power consumption. However, this method does not take into account a loss of a battery of the electronic device, resulting in errors in the calculated carbon emitted by the electronic device, and cannot accurately reflect the carbon emitted by the electronic device during the charging process.

### BRIEF DESCRIPTION OF THE DRAWINGS

FIG. 1 is a schematic structural diagram of an application scenario of a method for calculating carbon emitted by an electronic device provided by an embodiment of the present application.

FIG. 2 is a flowchart of a method for calculating carbon emitted by an electronic device provided by an embodiment of the present application.

FIG. 3 is a flowchart of a method for calculating carbon emitted by an electronic device provided by another embodiment of the present application.

FIG. 4 is a schematic diagram of an electronic device and an adapter with a first type provided by an embodiment of the present application.

FIG. 5 is a flowchart of a method for calculating carbon emitted by an electronic device provided by another embodiment of the present application.

### DETAILED DESCRIPTION

To facilitate understanding, some illustrations of concepts related to the embodiments of the present application are given by way of example for reference.

It should be noted that in the present application, “at least one” refers to one or more, and “a plurality of” refers to two or more than two. “And/or” describes a relationship between related objects and can indicate three types of relationships. For example, A and/or B can mean: A exists alone, A and B exist simultaneously, and B exists alone, wherein A and B can be singular or plural. The terms “first”, “second”, “third”, “fourth”, etc. (if present) in the description, claims and drawings of the present application are used to distinguish similar objects, rather than to describe a specific order or a sequence.

Electronic device will produce environmental pollutants such as carbon dioxide during a charging process. In related technologies, a method for calculating carbon emitted by the electronic device by detecting a battery capacity and a battery voltage of the electronic device are detected to calculate power consumption. However, this method does not take into account a loss of a battery of the electronic device, resulting in errors in the calculated carbon emitted by the electronic device, and cannot accurately reflect the carbon emitted by the electronic device generated by the electronic device during the charging process.

In order to solve the technical problem of low accuracy in calculating the carbon emitted by the electronic device of electronic devices, the embodiments of the present application provide a method for calculating carbon emitted by an electronic device, an electronic device and a storage medium. The following first describes an application scenario of the method for calculating carbon emitted by an electronic device of the present application.

FIG. 1 is a schematic structural diagram of an application scenario of a method for calculating carbon emitted by an electronic device provided by an embodiment of the present application. The method for calculating carbon emitted by an electronic device provided in an embodiment of the present application is applied to an electronic device 10, the electronic device 10 being in communication with an adapter 20, and the adapter 20 being in communication with a power supply device 30. The electronic device 10 obtains power from the power supply device 30 through the adapter 20.

The electronic device 10 being in communication with the adapter 20 through a wired communication connection mode and a wireless communication connection mode. The wired communication connection mode can provide one or more wired communication solutions, such as Universal Serial Bus (USB), Controller Area Network (CAN), etc. The wireless communication connection mode can provide one or more wireless communication solutions, such as wireless fidelity (Wi-Fi), Bluetooth (BT), mobile communication network, frequency modulation (FM), near field communication (NFC), and infrared (IR) technology, etc.

The electronic device 10 may be a device that needs to be charged, such as a laptop, a tablet computer, a mobile phone, a wearable device, etc. In addition, the electronic device 10 may also be an electronic device in an internet of things (IoT) system. The present application does not limit a type of the electronic device 10. The electronic device 10 includes, but is not limited to, a display screen 102, a register 103, a storage device 104, and at least one processor 105. The display screen 102, the register 103, the storage device 104, and the at least one processor 105 are communicated with each other via a communication bus 101.

The display screen 102 is provided with a display interface, and a plurality of controls are provided on the display interface. By clicking the controls, the display screen 102 can communicate with the register 103 via the communication bus 101 to obtain and display information fed back by the register 103. In one embodiment, by clicking a preset control related to carbon emitted by the electronic device on the display screen 102, the display screen 102 displays the carbon emitted by the electronic device which fed back by the register 103.

The register 103 may be an embedded controller (EC) chip, which is responsible for processing hardware interactions and communications with an operating system. For example, the register 103 may be used to process data from the adapter 20 and provide the data for the display screen 102.

The storage device 104 may be an electrically erasable programmable read-only memory (EEPROM), which is used to ensure that data is not lost after the electronic device 10 is powered off.

The at least one processor 105 is used to store one or more computer programs. One or more computer programs are configured to be executed by the processor 105. The one or more computer programs include a plurality of instructions. When the plurality of instructions is executed by the processor 105, the method for calculating carbon emitted by the electronic device executed on the electronic device 10 can be implemented.

The adapter 20 may be a charger corresponding to the electronic device 10, which is a transmission medium between the electronic device 10 and the power supply device 30 and is used to convert the AC power supply into DC power and perform voltage conversion on the DC power. The converted DC power can be input into the electronic device 10 through a charging cable to charge the battery of the electronic device 10.

FIG. 1 is only an example of the electronic device 10, and does not constitute a limitation on the electronic device 10. It may include more or less components than shown in the FIG. 1, or combine certain components, or different components. For example, the electronic device 10 may also include input and output devices, network access devices, etc.

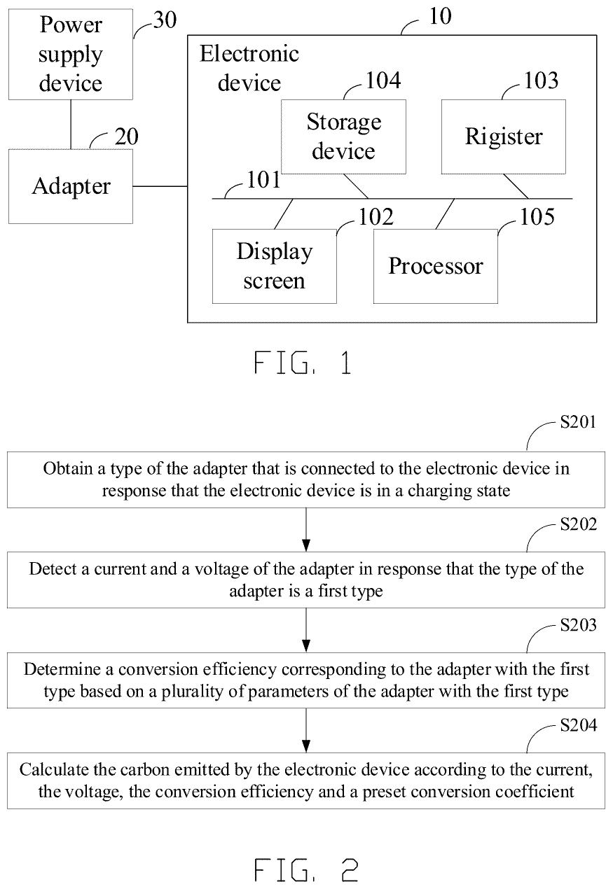

In order to solve the technical problem of low accuracy in calculating the carbon emitted by an electronic device, please refer to FIG. 2, which is a flow chart of a method for calculating carbon emitted by an electronic device provided in an embodiment of the present application. The method is applied in an electronic device (such as the electronic device 10 of FIG. 1). According to different requirements, the order of the steps in the flow chart can be changed, and some steps can be omitted.

Step S201, the electronic device obtains a type of the adapter 20 that is connected to the electronic device in response that the electronic device is in a charging state.

The electronic device in the embodiments of the present application may be a tablet computer, a laptop computer, a mobile phone, a wearable device, etc. The electronic device may also be referred to as a terminal device, a user equipment (UE), a mobile terminal (MT), an access terminal, a remote terminal, a mobile device, a user terminal, a terminal, a user device, etc. The storage capacity of the battery of the electronic device (for example, a mobile phone or a smart wearable device) is limited. In order to enable the electronic device to provide services to the user for a long time, the electronic device is connected to the power supply device through the adapter and can communicate with the adapter. The adapter can control a charging voltage or a charging current of the adapter to charge the electronic device, thereby providing power to the electronic device. The communication mode between the electronic device and the adapter includes a wired communication solution and a wireless communication solution, and the type of adapter connected to the electronic device can be determined according to different communication modes.

In some embodiments of the present application, the electronic device includes a charging interface, and the adapter includes a charging interface provided on the charging cable. When the charging interface of the electronic device is connected to the charging interface of the charging cable, it is determined that the electronic device is in the charging state, and it is determined that the communication mode between the electronic device and the adapter is a wired communication solution, and the type of the adapter is a wired adapter. Among them, the charging interface of the electronic device can be any one or more combinations of a universal serial bus Type-C (USB Type-C) interface, a lightning interface, and a micro-USB interface, and this application is not limited to this.

In some embodiments of the present application, the electronic device includes a wireless charging module (e.g., a wireless charging coil), and the electronic device detects that the wireless charging module is awakened, determines that the electronic device is in a charging state, and receives power transmitted by the adapter through wireless charging technology. It is determined that the communication mode between the electronic device and the adapter is a wireless communication mode, and the type of the adapter is a wireless adapter. Among them, wireless charging technology generally refers to a technology that transmits power through a wireless charging base station (e.g., Qi standard) or a charging pad.

In other embodiments of the present application, the electronic device determines whether the electronic device is in the charging state by detecting a remaining power of the battery. In one example, if the electronic device determines that the remaining power continues to increase, it is determined that the electronic device is in the charging state.

Step S202, the electronic device detects a current and a voltage of the adapter in response that the type of the adapter is a first type.

In at least one embodiment, the adapter may correspond to multiple types. In some embodiments of the present application, the adapter with the first type may be a wired adapter, which includes an alternating current (AC) interface and a direct current (DC) interface. The AC interface is used to connect to a power supply device. For example, the AC interface may be a plug of the adapter, which is connected to a socket corresponding to the power supply device through the plug. The DC interface may include a charging interface of the adapter, which is provided on a charging line and connected to an electronic device through the charging interface to provide direct current to the electronic device.

As an example, but not limitation, in some embodiments of the present application, taking the electronic device as a mobile phone as an example, the wired adapter can be a charger for the mobile phone. The charger collects AC power from the power supply device (for example, a socket connected to a mains power source) through the AC interface. The wired adapter converts the AC power into DC power and performs voltage conversion on the DC power. The converted DC power can be transmitted to the electronic device through the DC interface.

In some embodiments of the present application, the electronic device further includes an analog-to-digital converter (ADC), which is used to convert an analog signal into a digital signal. When the electronic device is in the charging state and the adapter with the first type, the current of the wired adapter at the DC interface and the voltage of the wired adapter at the DC terminal can be obtained through the analog-to-digital converter.

In one embodiment, the adapter sends analog signals (e.g., bus current, battery voltage, and charging voltage) to the ADC through the DC interface, and the ADC converts the analog signals into digital signals to obtain the current and voltage of the wired adapter.

Step S203, the electronic device determines a conversion efficiency corresponding to the adapter with the first type based on a plurality of parameters of the adapter with the first type.

In some embodiments of the present application, the plurality of parameters of the adapter with the first type may include but are not limited to specifications, an input voltage, an output voltage, an output current, an input current and an output power. Among them, the input voltage refers to a range of operation voltage of the adapter, the output voltage refers to a voltage required by the electronic device which is output from the power supply device and converted by the adapter, the output current refers to a current that the adapter can provide, the input power refers to a power consumed by the adapter from the power supply device, and the output power refers to a power provided by the adapter to the electronic device.

In one example, the electronic device determines a conversion efficiency according to the output power and the input power dynamically. For example, the conversion efficiency=(output power/input power)×100%. In another example, a fixed conversion efficiency can be obtained according to the specifications of the adapter, which is not limited in this application.

Step S204, the electronic device calculates the carbon emitted by the electronic device according to the current, the voltage, the conversion efficiency and a preset conversion coefficient.

In some embodiments of the present application, the conversion coefficient may indicate a power conversion value corresponding to the power generation type corresponding to the region where the current adapter is located. For example, the conversion coefficient of Albania is 0×6, 0.0111746 (floating point number), and the conversion coefficient of Algeria is 0×4, 0.5759669. Assuming that the conversion efficiency is dynamically calculated in real time, the power consumption of the AC interface of the adapter with the first type is calculated according to the current, the voltage and the conversion efficiency. For example, the power consumption of the AC interface of the adapter with the first type=(current×voltage)/conversion efficiency. The electronic device calculates the carbon emitted by the electronic device according to the power consumption of the AC interface of the adapter with the first type and the conversion coefficient. For example, the carbon emitted by the electronic device=the power consumption of the AC interface of the adapter with the first type×the conversion coefficient.

In an embodiment of the present application, when the adapter is of the first type, the electronic device detects the current and the voltage of the adapter with the first type and determines the conversion efficiency corresponding to the adapter with the first type. The electronic device calculates the carbon emitted by the electronic device of the electronic device based on the current, the voltage, the conversion efficiency and a preset conversion coefficient. The main body consumption of the electronic device can be calculated through the conversion efficiency without increasing the hardware cost, so that the calculated power consumption of the adapter is more accurate, thereby improving the calculation accuracy of the carbon emitted by the electronic device.

In other embodiments of the present application, since the adapter will generate high heat during charging for a long time, and the conversion efficiency of the adapter is related to the heat generated by the adapter. The high heat will lead to lower conversion efficiency. Part of the carbon emitted by the electronic device come from the heat. When the electronic device calculates the carbon emitted by the electronic device, if the conversion efficiency remains unchanged, it will affect electronic device calculates the carbon emitted by the electronic device based on the conversion efficiency.

In some embodiments of the present application, it is assumed that the conversion efficiency is a fixed parameter value. The electronic device detects a temperature of the adapter with the first type. If the temperature is greater than a preset temperature threshold, the electronic device calculates a temperature difference according to the detected temperature and the preset temperature threshold and calculates the carbon emitted by the electronic device caused by the heat consumption according to the temperature difference. When the conversion efficiency remains unchanged, the carbon emitted by the electronic device caused by the heat consumption is used as compensation for the temperature consumption. After the electronic device calculated the carbon emitted by the electronic device in step S203, the electronic device obtains a total carbon emitted by the electronic device of the electronic device by summing the carbon emitted by the electronic device caused by the heat consumption and the carbon emitted by the electronic device that is calculated according to the power consumption of the AC interface of the adapter with the first type and the conversion coefficient, which can improve the accuracy of calculating the carbon emitted by the electronic device generated by the electronic device during the charging process to a certain extent.

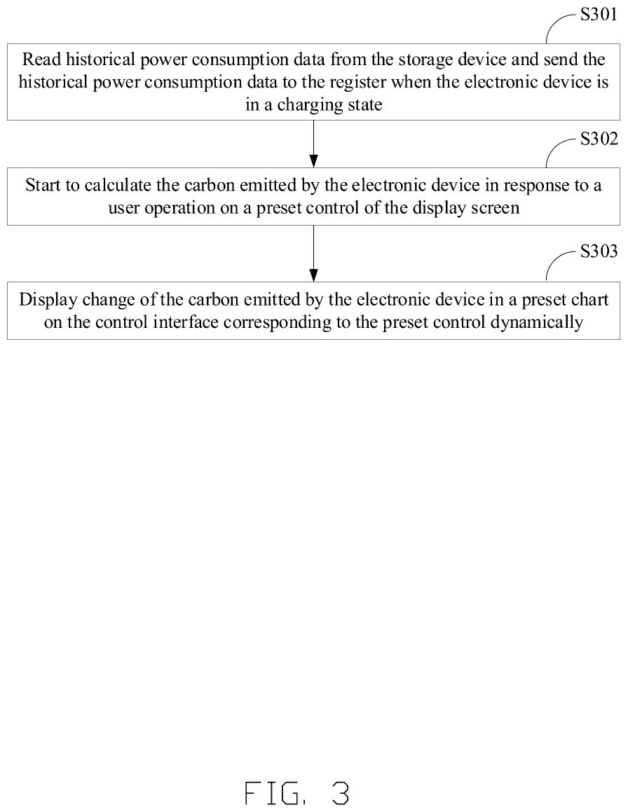

FIG. 3 is a flow chart of a method for calculating carbon emitted by the electronic device provided by another embodiment of the present application. As shown in FIG. 3, the electronic device further includes a display screen, and the display screen displays a display interface, and the display interface is provided with controls corresponding to multiple different application programs, including the following steps:

Step S301, the electronic device reads historical power consumption data from the storage device and sends the historical power consumption data to the register when the electronic device is in a charging state.

In some embodiments of the present application, since the storage device will not lose data after the electronic device is power off, and operation data of the electronic device is usually stored in the storage device, and the operation data includes the historical power consumption data. In one example, when it is detected that the storage device is changed from a charging state to a non-charging state, or the power consumption data cached in the register is greater than a first preset threshold, the power consumption data cached in the register can be stored in the storage device as historical power consumption data. The above is only an example, and the actual application is not limited to this.

In some embodiments of the present application, when the electronic device is in a charging state, it indicates that electronic device begins to emit carbon, in order to calculate the carbon emitted by the electronic device during the charging process and the historical carbon emitted by the electronic device. The electronic device reads historical power consumption data from the storage device and sends the historical power consumption data to the register when the electronic device is in a charging state, so that the register can update the total power consumption of the electronic device based on the historical power consumption data.

In other embodiments of the present application, in order to speed up the calculation efficiency of carbon emitted by the electronic device, when it is detected that the remaining power of the electronic device is less than or equal to a second preset threshold and the electronic device is in a non-charging state, it indicates that the electronic device needs to be charged as soon as possible to maintain the normal operation of the electronic device. The second preset threshold can be set according to actual conditions. For example, the second preset threshold is 10%. When the remaining power is less than or equal to 10% and the electronic device is in a non-charging state, the electronic device outputs a charging reminder message. The charging reminder message indicates that the electronic device needs to be charged and can be displayed by a charging indicator light to remind the user to charge the electronic device.

In some embodiments of the present application, the electronic device reads the historical power consumption data from the storage device and stores the historical power consumption data in the register when the electronic device detects the charging reminder message, thereby reducing the time for the electronic device to obtain historical power consumption data from the storage device during the charging process and improving the efficiency of calculating carbon emitted by the electronic device in the register.

Step S302, the electronic device starts to calculate the carbon emitted by the electronic device in response to a user operation on a preset control of the display screen.

In some embodiments of the present application, the electronic device includes a display screen, an interface is displayed on the display screen, and a plurality of controls are arranged on the display interface, each of which may correspond to at least one application or a function. By clicking on the control corresponding to the application, the application may be started. For example, a corresponding preset control is set for a carbon-related application, and the user triggers the electronic device to start calculating the carbon emitted by the electronic device by clicking on the preset control.

In some embodiments of the present application, a process of calculating the carbon emitted by the electronic device includes: the electronic device calculates power consumption data based on the current, the voltage and the conversion efficiency and stores the power consumption data in the register, the register calculates a total power consumption based on the historical power consumption data and the calculated power consumption data in responds to a user operation, and calculates the carbon emitted by the electronic device based on the total power consumption and the conversion coefficient.

In some embodiments of the present application, after the application is started, a system of the application can poll the carbon-related data in the register through the bus, and the carbon-related data can be the total power consumption, the carbon emitted by the electronic device, etc. When the system of the application polls the total power consumption and/or the carbon emitted by the electronic device, the total power consumption and the carbon emitted by the electronic device are displayed in real time on the control interface.

In other embodiments of the present application, the electronic device stores the total power consumption of the register in the storage device to avoid losing data corresponding to the total power consumption in response that a state of the electronic device is changed from a charging state to a non-charging state.

In another embodiment of the present application, the electronic device stores the total power consumption of the register in the storage device to avoid data loss in response that the electronic device is in a charging state.

In an embodiment of the present application, the electronic device stores the data calculated by the register (for example, the total power consumption) in the storage device timely, which can avoid data loss on the one hand, and ensure an accuracy of the total power consumption calculated in the subsequent recharging case on the other hand.

Step S303, the electronic device displays change of the carbon emitted by the electronic device in a preset chart on the control interface corresponding to the preset control dynamically.

In some embodiments of the present application, the electronic device enters a corresponding control interface in response to a click on the preset control and displays change of total power consumption and the carbon emitted by the electronic device in the preset chart of the control interface dynamically. The user can use the control interface to know the carbon emitted by the electronic device during the charging process and the total power consumption of the electronic device during its life cycle in real time.

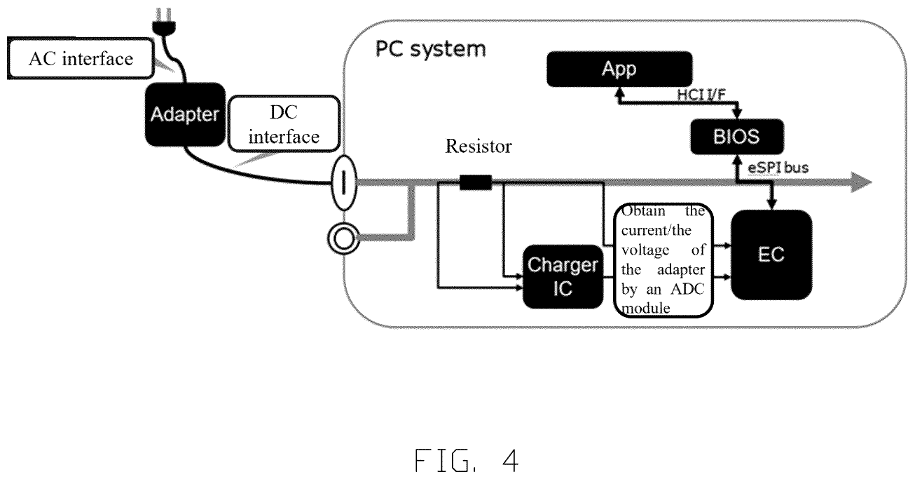

FIG. 4 is a schematic diagram of an electronic device and an adapter with a first type provided by an embodiment of the present application. As shown in FIG. 4, the adapter with the first type includes an AC interface and a DC interface. The PC system of the electronic device includes an application program (APP). The app is connected to the EC register through the HCI I/F protocol and the BIOS input/output bus. The electronic device also includes a battery charger management (Charger IC) chip for managing charging current and charging voltage. The analog-to-digital converter ADC module is connected to the Charger IC for obtaining the current and voltage of the adapter of the Charger IC, and then transmitting the current and voltage to the EC register.

In an embodiment of the present application, the electronic device displays the carbon emitted by the electronic device and total power consumption corresponding to the electronic device in real time through the control interface, thereby improving the user experience.

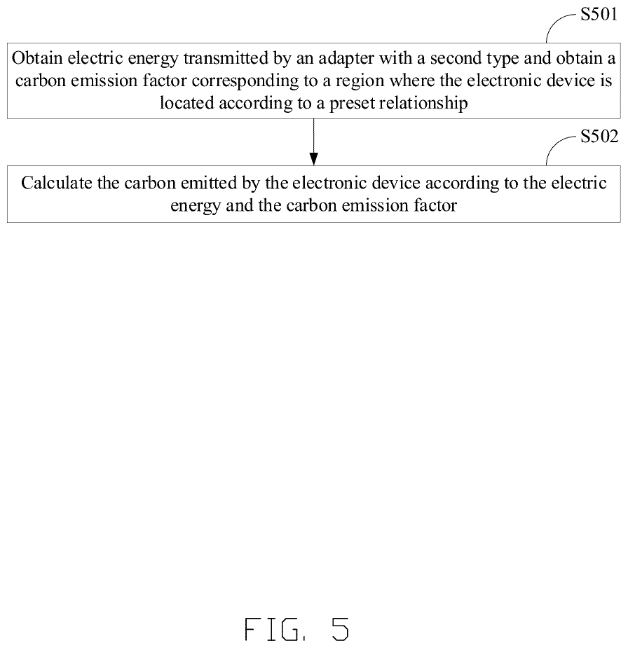

FIG. 5 is a flow chart of a method for calculating carbon emitted by an electronic device provided by another embodiment of the present application. As shown in FIG. 5, when it is determined that the type of the adapter is a second type, the steps shown in FIG. 5 may be performed as follows:

Step S501, the electronic device obtains electric energy transmitted by an adapter with a second type and obtains a carbon emission factor corresponding to a region where the electronic device is located according to a preset relationship.

In some embodiments of the present application, the electronic device determines that the adapter with the second type is connected to the electronic device in response that the electronic device has invoked a wireless charging module for charging. The electronic device obtains the electric energy transmitted by the adapter with the second type. Specifically, the electronic device sends an information acquisition instruction to the adapter with the second type, and the information acquisition instruction is used to instruct the adapter to feedback charging information, such as charging power, a voltage, a current, and charging protocol information. The electronic device receives the charging information fed back by the adapter with the second type, determines the charging power based on the charging information, and calculates the electric energy transmitted by the adapter with the second type based on the charging power and the charging time.

In some embodiments of the present application, the carbon emission factor corresponding to the region where the electronic device is located is obtained according to the preset relationship. The preset relationship may be a correspondence between a region and a type of power. In one example, the type of power is coal-fired power generation, and if the region where the electronic device is located is country C, then the carbon emission factor is approximately 0.996 kg of carbon dioxide emissions/kWh. In another example, the type of power is natural gas power generation, and if the region where the electronic device is located is country A, then the carbon emission factor is approximately 0.437 kg of carbon dioxide emissions/kWh.

Step S502, the electronic device calculates the carbon emitted by the electronic device according to the electric energy and the carbon emission factor.

In some embodiments of the present application, the carbon emitted by the electronic device=electrical energy×carbon emission factor. The unit of the carbon emitted by the electronic device is gram, the unit of the electrical energy is kilowatt-hour, and the unit of the carbon emission factor is gCO2/kWh.

In the embodiment of the present application, according to the determined type of adapter, the corresponding type of calculation process is executed, and the carbon emitted by the electronic devices corresponding to different types of adapters can be calculated in a targeted manner, which can improve the calculation accuracy of the carbon emitted by the electronic device of the electronic device to a certain extent. When the type of the adapter is the second type, it means that the communication transmission method between the adapter and the electronic device is wireless transmission. According to the type of electricity in the region where the electronic device is located and the relationship between the regional information, the carbon emission factor is determined, so that the carbon emitted by the electronic device is calculated based on the electric energy and the carbon emission factor, thereby improving the calculation accuracy of the carbon emitted by the electronic device.

In one embodiment, the storage device 104 may be an internal memory of the electronic device 10, that is, a memory built into the electronic device 10. In other embodiments, the storage device 104 may also be an external memory of the electronic device 10, that is, a memory externally connected to the electronic device 10.

In some embodiments, the storage device 104 is used to store program codes and various data, and to achieve high-speed and automatic access to programs or data during the operation of the electronic device 10.

The storage device 104 may include a random access memory and may also include a non-volatile memory, such as a hard disk, a memory, a plug-in hard disk, a smart media card (SMC), a secure digital (SD) card, a flash card (Flash Card), at least one disk storage device, a flash memory device, or other volatile solid-state storage devices.

In one embodiment, the processor 105 may be a central processing unit (CPU), or other general-purpose processors, digital signal processors (DSP), application-specific integrated circuits (ASIC), field-programmable gate arrays (FPGA) or other programmable logic devices, discrete gate or transistor logic devices, discrete hardware components, etc. A general-purpose processor may be a microprocessor, or the processor may be any other conventional processor, etc.

If the program code and various data in the storage device 104 are implemented in the form of software functional units and sold or used as independent products, they can be stored in a computer-readable storage medium. Based on this understanding, the present application implements all or part of the processes in the above-mentioned embodiment method, such as the method for calculating carbon emitted by the electronic device, and can also be completed by instructing the relevant hardware through a computer program. The computer program can be stored in a computer-readable storage medium, and the computer program can implement the steps of the above-mentioned various method embodiments when executed by the processor. Among them, the computer program includes computer program code, and the computer program code can be in source code form, object code form, executable file or some intermediate form, etc. The computer-readable medium may include: any entity or device that can carry the computer program code, recording medium, U disk, mobile hard disk, disk, optical disk, computer memory, read-only memory (ROM), etc.

It is understandable that the module division described above is a logical function division, and there may be other division methods in actual implementation. In addition, the functional modules in each embodiment of the present application may be integrated in the same processing unit, or each module may exist physically separately, or two or more modules may be integrated in the same unit. The above-mentioned integrated modules may be implemented in the form of hardware or in the form of hardware plus software functional modules.

Finally, it should be noted that the above embodiments are only used to illustrate the technical solutions of the present application and are not limiting. Although the present application has been described in detail with reference to the preferred embodiments, those of ordinary skill in the art should understand that the technical solutions of the present application can be modified. Modifications or equivalent substitutions may be made without departing from the spirit and scope of the technical solution of the present application.

What is claimed is:

1. A method for calculating carbon emitted by an electronic device using the electronic device, the method comprising:
obtaining a type of an adapter that is connected to the electronic device in response that the electronic device is in a charging state;
detecting a current and a voltage of the adapter in response that the type of the adapter is a first type;
determining a conversion efficiency corresponding to the adapter with the adapter with the first type based on a plurality of parameters of the adapter with the first type; and
calculating the carbon emitted by the electronic device according to the current, the voltage, the conversion efficiency and a preset conversion coefficient.

2. The method according to claim 1, wherein the electronic device comprises a register and a storage device, and the method further comprises:
reading historical power consumption data from the storage device and sends the historical power consumption data to the register, in response that the electronic device is in the charging state.

3. The method according to claim 2, wherein the electronic device comprises a display screen, the method further comprises:
starting to calculate the carbon emitted by the electronic device in response to a user operation on a preset control of the display screen, and
displaying change of the carbon emitted by the electronic device in a preset chart on a control interface corresponding to the preset control dynamically.

4. The method according to claim 3, wherein calculating a carbon emitted by the electronic device according to the current, the voltage, the conversion efficiency and a preset conversion coefficient comprises:
calculating power consumption data based on the current, the voltage and the conversion efficiency and storing the current power consumption data in the register;
calculating a total power consumption based on the historical power consumption data and the calculated power consumption data in responds to a user operation; and
calculating the carbon emitted by the electronic device based on the total power consumption and the conversion coefficient.

5. The method according to claim 4, further comprising:
storing the total power consumption of the register in the storage device in response that a state of the electronic device is changed from the charging state to a non-charging state; or
storing the total power consumption of the register in the storage device in response that the total power consumption is greater than a first preset threshold.

6. The method according to claim 1, further comprising:
obtaining electric energy transmitted by the adapter with a second type and obtaining a carbon emission factor corresponding to a region where the electronic device is located according to a preset relationship; and
calculating the carbon emitted by the electronic device according to the electric energy and the carbon emission factor.

7. The method according to claim 6, wherein obtaining electric energy transmitted by the adapter with the second type comprises:
sending an information acquisition instruction to the adapter with the second type;
receiving charging information fed back by the adapter with the second type;
determining the charging power based on the charging information; and
calculating the electric energy transmitted by the adapter with the second type based on the charging power and charging time.

8. The method according to claim 2, further comprising:
detecting a remaining power of the electronic device;
outputting a charging reminder message in response that the remaining power of the electronic device is less than or equal to a second preset threshold and the electronic device is in a non-charging state; and
reading the historical power consumption data from the storage device and storing the historical power consumption data in the register based on the charging reminder message.

9. An electronic device comprising:
a storage device;
at least one processor; and
the storage device storing one or more programs, which when executed by the at least one processor, cause the at least one processor to:
obtain a type of an adapter that is connected to the electronic device in response that the electronic device is in a charging state;
detect a current and a voltage of the adapter in response that the type of the adapter is a first type;
determine a conversion efficiency corresponding to the adapter with the first type based on a plurality of parameters of the adapter with the first type; and
calculate a carbon emitted by the electronic device according to the current, the voltage, the conversion efficiency and a preset conversion coefficient.

10. The electronic device according to claim 9, wherein the electronic device comprises a register and a storage device, the at least one processor is further caused to:
read historical power consumption data from the storage device and send the historical power consumption data to the register in response that the electronic device is in the charging state.

11. The electronic device according to claim 10, wherein the electronic device comprises a display screen, the at least one processor is further caused to:
start to calculate the carbon emitted by the electronic device in response to a user operation on a preset control of the display screen, and
display change of the carbon emitted by the electronic device in a preset chart on a control interface corresponding to the preset control dynamically.

12. The electronic device according to claim 11, wherein the at least one processor calculates a carbon emitted by the electronic device according to the current, the voltage, the conversion efficiency and a preset conversion coefficient by:
calculating power consumption data based on the current, the voltage and the conversion efficiency and storing the current power consumption data in the register;
calculating a total power consumption based on the historical power consumption data and the calculated power consumption data in responds to a user operation; and
calculating the carbon emitted by the electronic device based on the total power consumption and the conversion coefficient.

13. The electronic device according to claim 12, wherein the at least one processor is further caused to:
store the total power consumption of the register in the storage device in response that a state of the electronic device is changed from the charging state to a non-charging state; or
store the total power consumption of the register in the storage device in response that the total power consumption is greater than a first preset threshold.

14. The electronic device according to claim 9, wherein the at least one processor is further caused to:
obtain electric energy transmitted by the adapter with a second type and obtain a carbon emission factor corresponding to a region where the electronic device is located according to a preset relationship; and
calculate the carbon emitted by the electronic device according to the electric energy and the carbon emission factor.

15. The electronic device according to claim 14, wherein the at least one processor obtains electric energy transmitted by the adapter with the second type by:
sending an information acquisition instruction to the adapter with the second type;
receiving charging information fed back by the adapter with the second type;
determining the charging power based on the charging information; and
calculating the electric energy transmitted by the adapter with the second type based on the charging power and charging time.

16. The electronic device according to claim 10, wherein the at least one processor is further caused to:
detect a remaining power of the electronic device;
output a charging reminder message in response that the remaining power of the electronic device is less than or equal to a second preset threshold and the electronic device is in a non-charging state; and
read the historical power consumption data from the storage device and store the historical power consumption data in the register based on the charging reminder message.

17. A non-transitory storage medium having instructions stored thereon, when the instructions are executed by a processor of an electronic device, the processor is caused to perform a method for calculating carbon emitted by the electronic device, wherein the method comprises:
obtaining a type of an adapter that is connected to the electronic device in response that the electronic device is in a charging state;
detecting a current and a voltage of the adapter in response that the type of the adapter is a first type;
determining a conversion efficiency corresponding to the adapter with the adapter with the first type based on a plurality of parameters of the adapter with the first type; and
calculating the carbon emitted by the electronic device according to the current, the voltage, the conversion efficiency and a preset conversion coefficient.

18. The non-transitory storage medium according to claim 17, wherein the electronic device comprises a register and a storage device, the method further comprises:
reading historical power consumption data from the storage device and sends the historical power consumption data to the register in response that the electronic device is in the charging state.

19. The non-transitory storage medium according to claim 18, wherein the electronic device comprises a display screen, the method further comprises:
starting to calculate the carbon emitted by the electronic device in response to a user operation on a preset control of the display screen, and
displaying change of the carbon emitted by the electronic device in a preset chart on a control interface corresponding to the preset control dynamically.

20. The non-transitory storage medium according to claim 19, wherein
calculating a carbon emitted by the electronic device according to the current, the voltage, the conversion efficiency and a preset conversion coefficient comprises:
calculating power consumption data based on the current, the voltage and the conversion efficiency and storing the current power consumption data in the register;
calculating a total power consumption based on the historical power consumption data and the calculated power consumption data in responds to a user operation; and
calculating the carbon emitted by the electronic device based on the total power consumption and the conversion coefficient.
